(19) United States
(12) Patent Application Publication
(10) Pub. No.: US 2023/0116166 A1
(43) Pub. Date: Apr. 13, 2023

(54) DIE BONDING METHOD FOR MICRO-LED

(71) Applicant: LEDMAN OPTOELECTRONIC CO., LTD., Guangdong (CN)

(72) Inventors: Mantie Li, Guangdong (CN); Ling Xie, Guangdong (CN); Liang Yu, Guangdong (CN); Menglong Tu, Guangdong (CN)

(21) Appl. No.: 17/909,146

(22) PCT Filed: Sep. 3, 2020
(86) PCT No.: PCT/CN2020/113250

§ 371 Date: Sep. 2, 2022

(30) Foreign Application Priority Data
Mar. 4, 2020 (CN) 202010143743.X

(51) Int. Cl. H01L 33/00; H01L 33/62; H05K 3/34; H05K 3/24; H05K 3/28

(52) U.S. Cl. CPC H01L 33/005; H01L 33/62; H05K 3/243; H05K 3/282; H05K 3/3431; H05K 3/3489; H01L 2933/0066; H05K 2203/072

(57) ABSTRACT

A die bonding method for a micro-LED. The method includes plating tin at a die bonding position of a printed circuit board (PCB) to obtain a tin-plated layer; adding a protective layer and a flux layer on the tin-plated layer in sequence to obtain a pretreated PCB; and transferring a flip-chip micro-LED to the pretreated PCB, reflowing and die bonding to complete die bonding of the micro-LED.

### CROSS-REFERENCE TO RELATED APPLICATIONS

This is a National Stage Application filed under 35 U.S.C. 371 based on International Patent Application No. PCT/CN2020/113250, filed on Sept. 3, 2020, which claims priority to Chinese Patent Application No. 202010143743.X filed on Mar. 4, 2020, disclosures of both of which are incorporated herein by reference in their entireties.

### TECHNICAL FIELD

The present application belongs to the technical field of micro-LEDs, for example, a die bonding method for a micro-LED.

### BACKGROUND

As point spacing decreases, an arrangement density of chips increases. In the related art, a printed circuit board (PCB) in a gold plating process requires a printer to cooperate to print a solder paste. When the solder paste is printed, requirements for a steel mesh and accuracy of a printing process are higher. The steel mesh has small and dense openings, a smaller thickness, an increased cost and a shortened service life. A solder paste having a small particle size is required to fix a conventional chip through evacuating, filling with nitrogen and reflowing.

CN 110600496 A has disclosed a micro-LED chip packaged structure, which includes a circuit board, a micro-LED chip and a binding wire group. The circuit board has a non-functional region and a circuit connection region, and the non-functional region is adjacent to the circuit connection region. The micro-LED chip is located in the non-functional region, and a back surface of the micro-LED chip is in contact with and fixed on a front surface of the circuit board. In the binding wire group, one end of each binding wire is connected to an extraction electrode of the micro-LED chip, and the other end of the each binding wire is in contact with and connected to the circuit connection region of the circuit board.

CN 110718611 A has disclosed a method and apparatus for massively transferring micro-LEDs, a packaged structure and a display device. The method for massively transferring micro-LEDs includes: disposing a driver circuit substrate; disposing a first carrier plate and a second carrier plate; pouring out micro-LED elements on the second carrier plate; applying a vibration force to the first carrier plate and the second carrier plate; and bonding an electrode on the driver circuit substrate to the micro-LED elements. The apparatus for massively transferring micro-LEDs includes the components in the above method, the packaged structure is prepared through the above transfer method, and the display device includes the packaged structure. In the present application, the micro-LED elements are poured out on the second carrier plate in batches, and under the action of the vibration force, the micro-LED elements fall into the first carrier plate, achieving the massive transfer of the micro-LED elements after the micro-LED elements are bonded to the electrode.

CN 107527896 A has disclosed a micro-LED packaged structure based on red, green and blue (RGB) color rendering. The structure includes a body, where two independent cavities 1 and 2 are disposed on the body. A blue chip 1, a green chip and an encapsulation layer 1 are disposed in the cavity 1, and the encapsulation layer 1 completely wraps and encapsulates the blue chip 1 and the green chip. A blue chip 2 and an encapsulation layer 2 are disposed in the cavity 2, a red phosphor is disposed in the encapsulation layer 2, and the encapsulation layer 2 completely wraps and encapsulates the blue chip 2. The red phosphor completely absorbs blue light emitted from the blue chip 2 so that the cavity 2 emits red light only, and the red light emitted in the cavity 2 through the blue chip 2 and the red phosphor in the encapsulation layer 2 cooperates with the blue light emitted from the blue chip and the green light emitted from the green chip in the cavity 1, achieving the light emission of the three primary colors, and a color mixing effect is controlled by a current.

### SUMMARY

The present application provides a die bonding method for a micro-LED. The method can reduce a process flow of printing a solder paste with no need of using a solder paste printer and manufacturing a steel mesh, thereby improving efficiency.

Embodiments of the present application provide a die bonding method for a micro-LED. The method includes the steps below.

Tin is plated at a die bonding position of a PCB to obtain a tin-plated layer.

A protective layer and a flux layer are added on the tin-plated layer in sequence to obtain a pretreated PCB.

A flip-chip micro-LED is transferred to the pretreated PCB, reflowed and die bonded to complete die bonding of the micro-LED.

### BRIEF DESCRIPTION OF DRAWINGS

FIG. 1 is a structure diagram of a die bonding method for a micro-LED according to a specific embodiment of the present application.

FIG. 2 is a structure diagram of a PCB used in a specific embodiment of the present application.

### DETAILED DESCRIPTION

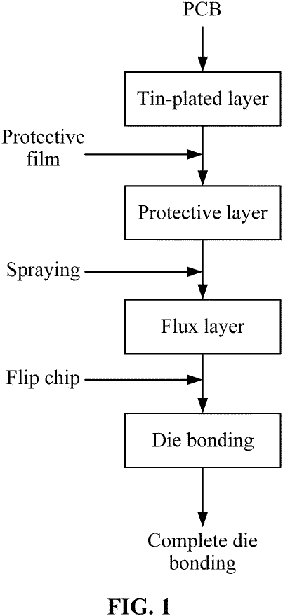

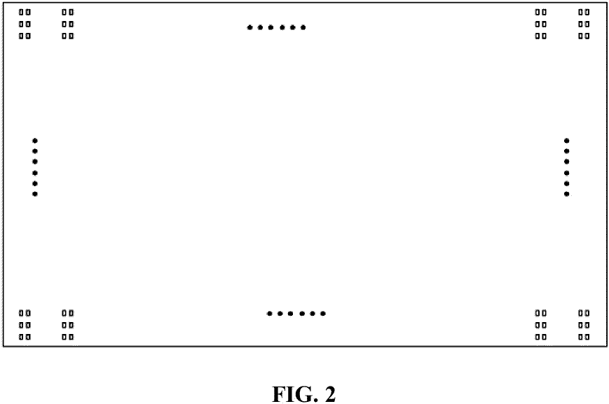

As shown in FIGS. 1 and 2, FIG. 1 is a structure diagram of a die bonding method for a micro-LED according to an embodiment of the present application, and FIG. 2 is a structure diagram of a PCB used in an embodiment of the present application.

### Embodiment One

The present embodiment provides a die bonding method for a micro-LED. The method includes the steps below.
(1) Tin is plated at a die bonding position of a PCB to obtain a tin-plated layer having a thickness of 15 µm.
(2) A protective layer and a flux layer are added on the tin-plated layer obtained in step (1) in sequence, where the flux layer has a thickness of 1 µm. A method for adding the protective layer is to stick a protective film, and the flux layer uses a spraying process to obtain a pretreated PCB.
(3) A flip-chip micro-LED with tin is transferred to the pretreated PCB obtained in step (2), a reflow profile is adjusted, and then reflowed and die bonded to complete die bonding of the micro-LED.

### Embodiment Two

The present embodiment provides a die bonding method for a micro-LED. The method includes the steps below.
(1) Tin is plated at a die bonding position of a PCB to obtain a tin-plated layer having a thickness of 30 µm.
(2) A protective layer and a flux layer are added on the tin-plated layer obtained in step (1) in sequence, where the flux layer has a thickness of 5 µm. A method for adding the protective layer is to stick a protective film, and the flux layer uses a spraying process to obtain a pretreated PCB.
(3) A flip-chip micro-LED with tin is transferred to the pretreated PCB obtained in step (2), a reflow profile is adjusted, and then reflowed and die bonded to complete die bonding of the micro-LED.

### Embodiment Three

The present embodiment provides a die bonding method for a micro-LED. The method includes the steps below.
(1) Tin is plated at a die bonding position of a PCB to obtain a tin-plated layer having a thickness of 20 µm.
(2) A protective layer and a flux layer are added on the tin-plated layer obtained in step (1) in sequence, where the flux layer has a thickness of 2 µm. A method for adding the protective layer is an organic solderability preservative (OSP) process, and the flux layer uses a spraying process to obtain a pretreated PCB.
(3) A flip-chip micro-LED with tin is transferred to the pretreated PCB obtained in step (2), a reflow profile is adjusted, and then reflowed and die bonded to complete die bonding of the micro-LED.

### Embodiment Four

The present embodiment provides a die bonding method for a micro-LED. The method includes the steps below.
(1) Tin is plated at a die bonding position of a PCB to obtain a tin-plated layer having a thickness of 25 µm.
(2) A protective layer and a flux layer are added on the tin-plated layer obtained in step (1) in sequence, where the flux layer has a thickness of 3 µm. A method for adding the protective layer is an OSP process, and the flux layer uses a spraying process to obtain a pretreated PCB.
(3) A flip-chip micro-LED with tin is transferred to the pretreated PCB obtained in step (2), a reflow profile is adjusted, and then reflowed and die bonded to complete die bonding of the micro-LED.

The tin plating method used in embodiments one to four of the present application is an electroless tin plating method. Under the action of a reductant, metal ions in a plating solution are deposited on an active surface of a matrix. A tin layer formed through the electroless tin plating has a uniform thickness, and no external power supply is required.

The reflowing and die bonding process used in embodiments one to four of the present application includes evacuating and filling with nitrogen to correct a negative pressure, where the nitrogen has a concentration greater than 99.99%.

The protective film used in embodiments one and two is a ultraviolet (UV) curable film. A material type of the OSP process in embodiments three and four includes rosins, active resins and azoles, and the azole OSP is selected in the present embodiment. The protective film requires to be torn off when in use, and the die bonding and the reflowing are completed within an operable time limit.

Compared with the gold plating method in the related art, the die bonding method for a micro-LED used in embodiments one to four of the present application can save a cost by 20% to 30%.

Compared with the related technical solution, the present application has at least the beneficial effects described below.

In the present application, the process of tin plating and an anti-oxidation layer is used instead of the gold plating and reduces the cost of the PCB by 20% to 30%. In cooperation with a flip chip which has an electrode with tin, the process can reduce a process flow of printing a solder paste with no need of using a solder paste printer and manufacturing a steel mesh, thereby improving efficiency.

What is claimed is:

1. A die bonding method for a micro-LED, comprising:
plating tin at a die bonding position of a printed circuit board (PCB) to obtain a tin-plated layer;
adding a protective layer and a flux layer on the tin-plated layer in sequence to obtain a pretreated PCB; and
transferring a flip-chip micro-LED to the pretreated PCB, reflowing and die bonding to complete die bonding of the micro-LED.

2. The method according to claim 1, wherein the tin-plated layer has a thickness of 5-30 µm.

3. The method according to claim 1, wherein adding the protective layer comprises one of sticking a protective film or an organic solderability preservative (OSP) process.

4. The method according to claim 1 , wherein a flux comprises at least one of the following organic no-clean fluxes:
ketones, alcohols or esters.

5. The method according to claim 1 , wherein the flux layer has a thickness of 1-5 µm.

6. The method according to claim 1 , wherein the flip-chip micro-LED is a flip-chip micro-LED with tin.

7. The method according to claim 1 , further comprising adjusting a reflow profile before the reflowing and the die bonding.

8. The method according to claim 1 , wherein the reflowing and the die bonding comprise evacuating and filling with nitrogen to correct a negative pressure, wherein the nitrogen has a concentration greater than 99.99%.

9. The method according to claim 1 , wherein the tin-plated layer has a thickness of 530 µm;
wherein the flux layer has a thickness of 1-5 µm, and the method for adding the protective layer comprises any one of sticking the protective film or the OSP process.

10. The method according to claim 2, wherein adding the protective layer comprises one of sticking a protective film or an organic solderability preservative (OSP) process.

11. The method according to claim 2, wherein a flux comprises at least one of the following organic no-clean fluxes: ketones, alcohols or esters.

12. The method according to claim 3, wherein a flux comprises at least one of the following organic no-clean fluxes: ketones, alcohols or esters.

13. The method according to 2, wherein the flux layer has a thickness of 1-5 µm.

14. The method according to 3, wherein the flux layer has a thickness of 1-5 µm.

15. The method according to 4, wherein the flux layer has a thickness of 1-5 µm.

16. The method according to claim 2, wherein the flip-chip micro-LED is a flip-chip micro-LED with tin.

17. The method according to claim 3, wherein the flip-chip micro-LED is a flip-chip micro-LED with tin.

18. The method according to claim 4, wherein the flip-chip micro-LED is a flip-chip micro-LED with tin.

19. The method according to claim 5, wherein the flip-chip micro-LED is a flip-chip micro-LED with tin.

20. The method according to claim 2, further comprising adjusting a reflow profile before the reflowing and the die bonding.
